(19) United States
(12) Patent Application Publication
(10) Pub. No.: US 2018/0031652 A1
(43) Pub. Date: Feb. 1, 2018

(54) MAGNETIC RESONANCE IMAGING APPARATUS AND METHOD WITH SLICE-SPECIFIC ADJUSTMENT OF RADIO FREQUENCY PULSES TO CURRENT AMBIENT CONDITIONS

(71) Applicant: Siemens Healthcare GmbH, Erlangen (DE)

(72) Inventors: Dominik Paul, Bubenreuth (DE); Mario Zeller, Erlangen (DE)

(73) Assignee: Siemens Healthcare GmbH, Erlangen (DE)

(21) Appl. No.: 15/662,605

(22) Filed: Jul. 28, 2017

(30) Foreign Application Priority Data
Jul. 29, 2016 (DE) 102016214088.4

(51) Int. Cl. G01R 33/44; G01R 33/483

(52) U.S. Cl. CPC G01R 33/446; G01R 33/4835

(57) ABSTRACT

A method according to the invention for the slice-specific adjustment of RF pulses when recording MR signals of an examination subject with the use of a slice multiplexing method in which MR signals from at least two different slices of the examination subject are detected simultaneously when recording the MR signals, has the following steps. The respective position of the slices to be simultaneously detected in the examination subject are determined and designated in a processor. For each slice to be detected simultaneously, monoslice RF pulse parameters are determined in the processor based on the determined position of the respective slice. The monoslice RF pulse parameters are corrected in the processor based on at least one examination subject-specific parameter map, which maps the spatial distribution of a system parameter in the examination subject, and the determined position. A multiband RF pulse is determined in the processor, for manipulation of the slices to be detected simultaneously based on the corrected monoslice RF pulse parameters. An electronic signal is emitted by the processor that represents the RF pulse, in a form useable to operate the MR scanner in the acquisition of the MR signals.

### BACKGROUND OF THE INVENTION

### Field of the Invention

The invention concerns a magnetic resonance (MR) slice multiplexing method and apparatus, which permit a slice-specific adjustment of radio-frequency (RF) pulses to current ambient conditions.

### Description of the Prior Art

MR technology is a known modality with which images from the inside of an examination subject are generated. For this purpose, the examination subject is positioned, in an MR data acquisition scanner, in a strong static, homogenous basic magnetic field, also referred to as a B₀ field, with a field strength of 0.2 Tesla to 7 Tesla and more, that causes nuclear spins in the subject to be oriented along the basic magnetic field. To trigger nuclear magnetic resonance signals, radio frequency excitation pulses (RF pulses) are emitted into the subject. The triggered MR signals are entered as numerical values into a memory, as so-called k-space data. MR images reconstructed or spectroscopic data are determined from the k-space data. For spatial encoding of the measurement data, rapidly switched magnetic gradient fields are superimposed on the basic magnetic field. The acquired measurement data are digitized and stored as complex numerical values in a k-space matrix. An associated MR image can be reconstructed from the k-space matrix populated with such values, such as by a multidimensional Fourier transformation.

The desire for ever faster acquisition of MR images in the clinical environment has resulted in a number of MR data acquisition methods in which several images are recorded simultaneously. In general, these methods can be characterized by focused transverse magnetization of at least two slices being employed simultaneously for the imaging process (“multislice imaging”, “slice multiplexing”) for at least part of the measurement. By contrast, with conventional “multislice imaging” signals from at least two alternating slices are recorded, i.e. completely independently of each other, with a correspondingly longer measurement period.

Known methods for this purpose are, so-called Hadamard encoding, methods with simultaneous echo refocusing, methods with broadband data recording as well as methods which employ parallel imaging in the direction of slices. The latter methods also include, for example, blipped CAIPI technology, as described by Setsompop et al. in “Blipped-Controlled Aliasing in Parallel Imaging for Simultaneous Multislice Echo Planar Imaging With Reduced g-Factor Penalty”, Magnetic Resonance in Medicine 67, 2012, p. 1210-1224.

In such slice multiplexing methods, a so-called multiband RF pulse is used to simultaneously excite or otherwise manipulate (e.g. to refocus or to saturate) two or more slices. Such a multiband RF pulse is, for example, a multiplex of individual RF pulses which would be used to manipulate the individual slices for manipulation simultaneously. To be able to separate the data sets in k-space that respectively result from signals originating from the different slices, a different phase is imposed on each of the individual RF pulses before multiplexing, such as by adding a linear phase increase, which results in the slices in the local area being pushed against each other. By multiplexing a baseband-modulated multiband RF pulse is obtained by totaling the pulse shapes of the individual RF pulses.

As described in the aforementioned article by Setsompop et al., g-factor disadvantages can be reduced by displacements between the slices by using gradient blips or modulating the phases of the individual RF pulses accordingly. As also described in the aforementioned article by Setsompop et al., the signals from the simultaneously triggered or otherwise manipulated slices can first be summarized as signals from only one slice, which are then separated by a slice GRAPPA method (GRAPPA: “Generalized Autocalibrating Partial Parallel Acquisition”) in subsequent processing.

MR methods, both tomographic imaging (MRT, magnetic resonance tomography) and spectroscopy (MRS, magnetic resonance spectroscopy) generally require “benign” physical ambient conditions in order to ensure the recorded data are of the best possible quality. This pertains to any or all of spatial homogeneity, temporal stability and absolute precision of the magnetic fields relevant to MR methods (B₀, the stationary basic magnetic field and B₁, the radio frequency alternating magnetic field).

Measures are known with which deviations from ideal ambient conditions can be at least partially offset. These include both system-specific settings, which aim to correct the conditions of the MR system that is used, such as eddy current-induced dynamic field disturbances as well as gradient sensitivities. Such measures also include settings specific to the examination subject, such as susceptibility-based static field disturbances or spatial variations of the radio frequency field, which aim to offset the changes caused by the examination subject introduced into the measuring volume of the MR scanner, such as a patient. In order to offset ambient conditions that are not ideal, affected parameters can be adjusted to the measurement sequences. In particular, the respective central frequency (for example, for improved fat suppression and/or reduced EPI image displacement), a first-order shimming of the B0 field (for example, for more homogenous fat suppression and/or an improved signal-to-noise ratio (SNR)), a respective voltage of the RF transmitter units (for example, for an improved SNR) as well as B1 shimming (for example, for a more homogenous SNR) are examples of such parameters. Such examination subject-specific parameters can be derived from B0 field maps or B1 field maps, for example, which may be created before the actual diagnostic scan.

Conventionally, however, an adjustment of these parameters has only been possible for connected volumes, and not for unconnected slices such as those simultaneously triggered or manipulated for slice multiplexing. Because the slices to be simultaneously manipulated are normally arranged as far as possible from each other so as to make later separation of the signals easier in the case of slice multiplexing methods, such conventional methods correct variations of the ambient conditions in an optimization volume composed of either the entire slice stack to be measured, or at least the envelope of the slices to be simultaneously manipulated. The parameters obtained in this way are therefore adjusted only as an average over the optimization volume, and the adjustment may be poor for the actual slices concerned. Particularly in the case of measurements of areas of the examination subject with rapidly varying spatial ambient conditions, such as in the head area of patients, such adjustments of parameters averaged over larger volumes can lead to a degradation in the resulting image.

### SUMMARY OF THE INVENTION

An object of the invention is to enable a slice-specific adjustment of RF pulses when recording MR signals of an examination subject with the use of a slice multiplexing method, wherein slice-specific adjustments of parameters are made in order to offset ambient conditions differing from ideal ambient conditions.

A method according to the invention for the slice-specific adjustment of RF pulses when recording MR signals of an examination subject with the use of a slice multiplexing method in which MR signals from at least two different slices of the examination subject are detected simultaneously when recording the MR signals, has the following steps. The respective position of the slices to be simultaneously detected in the examination subject are determined and designated in a processor. For each slice to be detected simultaneously, monoslice RF pulse parameters are determined in the processor based on the determined position of the respective slice. The monoslice RF pulse parameters are corrected in the processor based on at least one examination subject-specific parameter map, which maps the spatial distribution of a system parameter in the examination subject, and the determined position. A multiband RF pulse is determined in the processor, for manipulation of the slices to be detected simultaneously based on the corrected monoslice RF pulse parameters. An electronic signal is emitted by the processor that represents the RF pulse, in a form useable to operate the MR scanner in the acquisition of the MR signals.

Through the correction according to the invention of the monoslice RF pulse parameters based on at least one examination subject-specific parameter map, the monoslice RF pulse parameters can be adjusted to current ambient conditions. Through the creation according to the invention of multiband RF pulses based on the already-corrected monoslice RF pulse parameters, resulting multiband RF pulses are themselves adjusted slice-specifically to current ambient conditions. Monoslice RF pulses that are already adjusted slice-specifically thus can be combined with the likewise slice-specifically adjusted multiband RF pulses by multiplexing, as a result of which the SNR and the homogeneity of the SNR in all the slices and, if applicable, also fat suppression, can be improved with slice precision in each case.

A magnetic resonance apparatus according to the invention has an MR data acquisition scanner with a basic field magnet, a gradient coil arrangement, a radio frequency antenna, and a control computer configured to operate the scanner so as to perform the method according to the invention, with a radio frequency transmit/receive controller having a multiband RF pulse unit.

The present invention also encompasses a non-transitory, computer-readable data storage medium that is encoded with programming instructions, the storage medium being loadable into a computer or computer system of a magnetic resonance imaging apparatus, and the programming instructions causing the computer or computer system to operate the magnetic resonance imaging apparatus in order to implement any or all of the embodiments of the inventive method, as described above.

The advantages and embodiments described with regard to the method apply analogously to the MR apparatus and the electronically readable data medium.

### BRIEF DESCRIPTION OF THE DRAWINGS

FIG. 1 schematically illustrates a magnetic resonance system according to the invention.

FIG. 2 is a flowchart of the method according to the invention.

### DESCRIPTION OF THE PREFERRED EMBODIMENTS

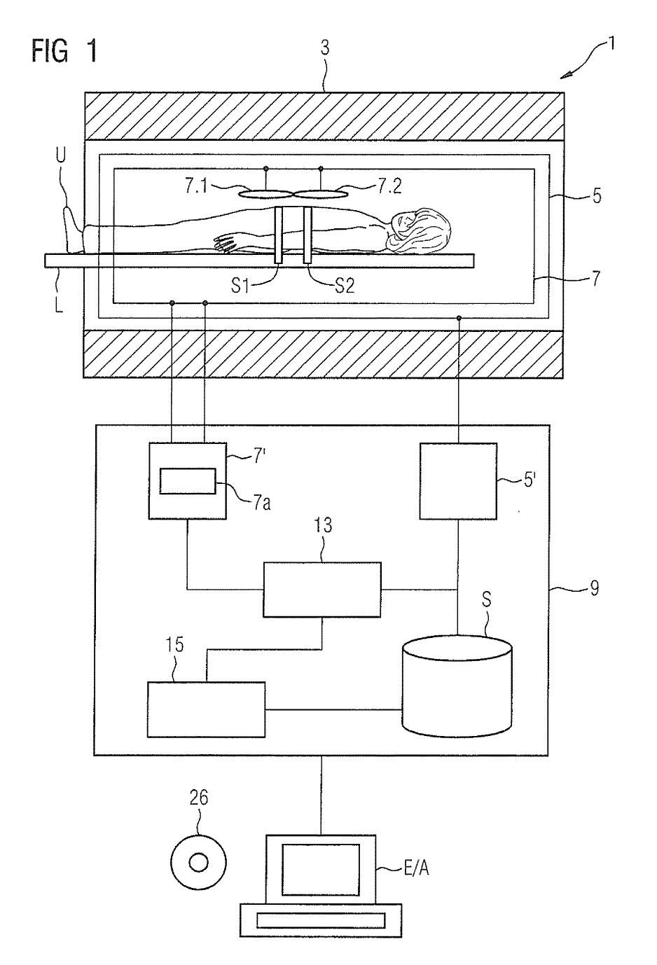

FIG. 1 schematically illustrates a magnetic resonance apparatus 1 according to the invention. This has a scanner 3 with a basic field magnet that generates a basic magnetic field, a gradient coil arrangement 5 that generates gradient fields, a radio frequency antenna arrangement 7 that emits and receives radio frequency signals, and a control computer 9 designed to execute the method according to the invention. In FIG. 1 these components of the magnetic resonance apparatus 1 are only shown schematically. In particular, the radio frequency antenna arrangement 7 may several coils such as coils 7.1 and 7.2 shown schematically, or more coils that can be designed either only for transmitting radio frequency signals or only for receiving the triggered radio frequency MR signals, or for both.

In order to acquire MR data from an examination subject U, for example a patient or a phantom, the subject U is introduced into the measuring volume of the scanner 3 on a bed L. The slices S1 and S2 exemplify two different slices S1 and S2 of the subject U, which can be simultaneously detected when recording MR signals.

The control computer 9 controls the scanner 3, and in particular the gradient coil arrangement 5, via a gradient controller 5′, and the radio frequency antenna arrangement 7 via a radio frequency transmit/receive controller 7′. The radio frequency controller 7′ may have several channels in which signals can be transmitted or received.

The radio frequency unit 7 together with its radio frequency transmit/receive controller 7′ is responsible for the generation and emission of a radio frequency field (and thus forms an RF radiator), in order to manipulate the nuclear spins in an area (for example, in various slices S1 and S2) of the examination subject U. The center frequency of the radio frequency alternating field, also referred to as the B1 field, must be close to the resonance frequency of the spins to be manipulated. To generate the B1 field, controlled currents are applied to the RF coils in the radio frequency antenna arrangement 7 by the radio frequency transmit/receive controller 7′. A multiband RF pulse unit 7a according to the invention, which may include the radio frequency transmit/receive controller 7′, calculates multiband RF pulses for the simultaneous manipulation of various slices S1, S2 in the object for examination U.

Furthermore, the control computer 9 has a correction processor 15 and is designed to execute the method according to the invention for the slice-specific adjustment of RF pulses when recording MR signals of the examination subject U with the use of a slice multiplexing method in which MR signals are detected simultaneously from at least two different slices of the examination subject U when recording the MR signals.

An arithmetic unit 13 that includes the control computer 9 is designed to perform all the necessary arithmetic operations for the necessary measurements and provisions. Interim results, and results required for this or ascertained in doing so, are stored in a memory S of the control computer 9. The components shown here need not necessarily be physically separate units, but merely exemplify a breakdown into units in terms of functions, which can also be realized as fewer or even as only one physical unit.

Control commands can be directed to the magnetic resonance apparatus 1 and/or results of the control computer 9 such as image data, are displayed at an input/output device I/O of the magnetic resonance apparatus 1.

The method described herein can also be in the form of program code that causes the described method to be implemented by the control computer 9 when executed therein. An electronically readable data storage medium 26 with the electronically readable control information (code) stored thereon may be used.

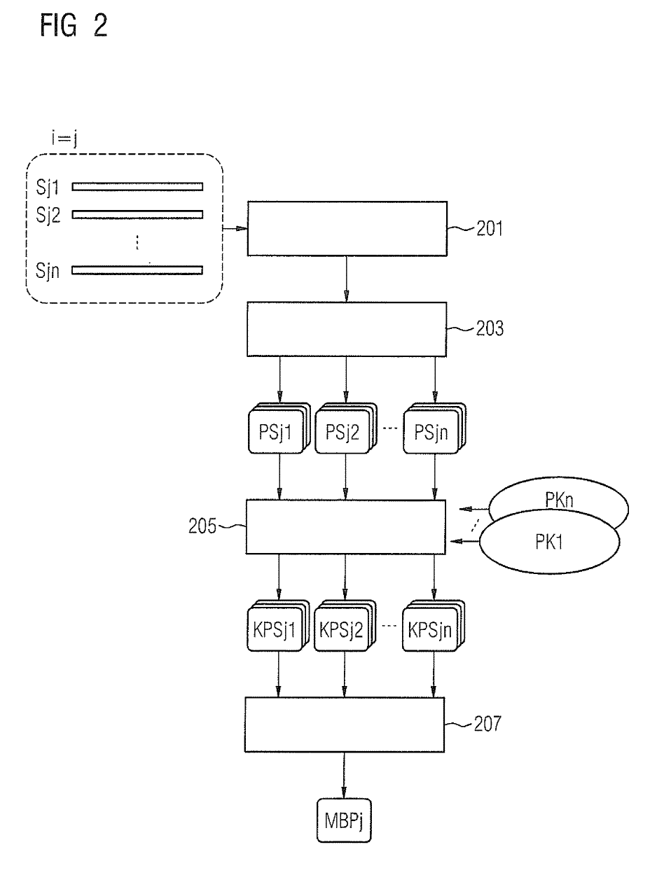

In FIG. 2, a flowchart of a method according to the invention is shown. For a set j having i=1, . . . , N sets of n different slices Sj1, Sj2, . . . Sjn the spins of which are to be simultaneously manipulated with an RF pulse and from which MR signals are to be simultaneously detected when recording, in a step 201 the respective positions of the slices to be detected simultaneously Sj1, Sj2, . . . , Sjn are determined in the object for examination, wherein both N and n is in each case a natural number greater than or equal to 2.

The determination of the positions of the slices to be detected simultaneously (step 201) may include the selection of one of the slices Sj1, Sj2, . . . , Sjn to be detected simultaneously as an output slice and the determination of the distance of each further slice to be detected simultaneously from the output slice.

Based on the respective determined position, in a further step 203, monoslice RF pulse parameters PSj1, PSj2, . . . , PSjn are determined for each slice to be detected simultaneously Sj1, Sj2, . . . , Sjn.

A monoslice RF pulse parameter to be determined can be, for example, a respective central excitation frequency f0 of the slices to be detected simultaneously Sj1, Sj2, . . . , Sjn.

In addition, or alternatively, a monoslice RF pulse parameter to be determined can in each case be an amplitude scaling factor of the slices to be detected simultaneously Sj1, Sj2, . . . , Sjn, which adjusts the amplitude of a monoslice RF pulse regulated by way of transmitter power.

Likewise, in addition or alternatively, a monoslice RF pulse parameter to be determined can in each case be a B1 shimming parameter of the slices to be detected simultaneously Sj1, Sj2, . . . Sjn. Here a B1 shimming parameter of a slice to be detected simultaneously Sj1, Sj2, . . . , Sjn can, in particular, establish the settings (for example, phase and amplitude) of several, for example, at least two, used channels of a used high frequency send/receive controller.

In a further step 205, the particular monoslice RF pulse parameters are corrected on the basis of at least one examination object-specific parameter map PK1, . . . , PKn, which in each case maps the spatial distribution of a system parameter in the object for examination and thus prevailing ambient conditions, and on the basis of the position determined in each case for the corresponding slice Sj1, Sj2, . . . , Sjn to corrected monoslice RF pulse parameters KPSj1, KPSj2, . . . , KPSjn.

In particular, a B0 field map and/or a B1 field map are considered as examination object-specific parameter maps PK1, . . . , PKn. The examination object-specific parameter maps PK1, . . . , PKn can already be recorded using a common method before the start of slice multiplexing measurement or also, for example, ascertained nested with this.

Based on a B0 field map as an examination object-specific parameter map PK1, . . . , PKn, for each slice to be detected simultaneously Sj1, Sj2, . . . Sjn, a corrected central excitation frequency ID can be determined for a monoslice RF pulse to manipulate the respective slice.

By means of a corrected central excitation frequency f0, fat suppression, for example, can be improved or, where an EPI technique is used, image displacement reduced.

Using the corrected central excitation frequency f0, a monoslice RF pulse phase progression of a monoslice RF pulse of the corresponding slice to be detected simultaneously can be adjusted for each slice to be detected simultaneously Sj1, Sj2, . . . , Sjn. A phase increase between adjacent slices to be detected simultaneously in accordance with a difference in their respectively corrected central excitation frequencies is imposed on the phases of the monoslice RF pulses of the corresponding slices. This phase increase can be linear, for example.

Based on a B1 field map as an examination subject-specific parameter map PK1, . . . , PKn, for each slice to be detected simultaneously Sj1, Sj2, . . . , Sjn, a corrected amplitude scaling factor can be determined for a monoslice RF pulse to manipulate the respective slice. By correcting the amplitude scaling factor, the SNR can be improved.

Likewise, based on a B1 field map as an examination object-specific parameter map PK1, PKn, for each slice to be detected simultaneously Sj1, Sj2, . . . , Sjn, a corrected B1 shimming parameter can be determined for a monoslice RF pulse to manipulate the respective slice. The correction of the B1 shimming parameter for a monoslice RF pulse enables a more homogenous SNR.

Based on the corrected monoslice RF pulse parameter KPSj1, KPSj1, . . . , KPSjn, in a further step 207 a multiband RF pulse MBPj is created to manipulate the slices to be detected simultaneously Sj1, Sj2, . . . , Sjn of the set j. The creation of the multiband RF pulse MBPj may, in particular, comprise a totaling of, in particular complex values of, monoslice-RF pulses matching the corrected monoslice RF pulse parameters KPSj1, KPSj1, . . . , KPSjn.

As a result of the monoslice RF pulse parameters PSj1, PSj1, . . . , PSjn first being corrected to corrected monoslice RF pulse parameters KPSj1, KPSj1, . . . , KPSjn before the multiband RF pulse MBPj is created on the basis of these monoslice RF pulse parameters KPSj1, KPSj1, . . . , KPSjn corrected and thus adjusted to prevailing ambient conditions, it is possible to ensure that the multiband RF pulse MBPj itself is likewise precisely adjusted for the slices Sj1, Sj2, . . . Sjn to be simultaneously manipulated by it. A compromise in the adjustment of the slices to be simultaneously manipulated Sj1, Sj2, . . . , Sjn is no longer necessary.

The steps 201 to 207 can be repeated for all the sets j of slices to be simultaneously manipulated and detected Sj1, Sj2, . . . , Sjn, for sets which are desired in a measurement.

In an exemplary embodiment, the creation of the multiband RF pulse may comprise a gradient moment-based Maxwell term correction method as described, for example, in DE102012205587.

It is also possible for the creation of the multiband RF pulse to include a B0 shimming method, in particular of the first order, for example, to enable more homogenous fat suppression and/or an improved SNR. Such a B0 shimming method can be performed, for example, by gradient offsets averaged on the basis of volumes filled across the entirety of the slices to be measured in the object for examination or at least the envelope of the set j of slices to be simultaneously manipulated and detected Sj1, Sj2, . . . , Sjn.

With the multiband RF pulses thus obtained, a slice multiplexing measurement can be performed, in which MR signals are detected simultaneously from at least two different slices of the examination subject U when recording the MR signals. The simultaneously detected MR signals can then, for example, be separated again using the aforementioned GRAPPA method to enable separate reconstruction and display images of the respective slices. The multiband RF pulses created according to the invention are slice-specifically adjusted to current ambient conditions.

Such an adjustment of the multiband RF pulse which is also dynamically possible improves the achievable quality of measured data and thus of the reconstructed image data.

It is expected that EPI measurement techniques with multiband RF pulses created according to the invention will benefit particularly from the slice-specific adjustment achieved for the individual slices to be simultaneously manipulated. However, the method according to the invention can be used in the context of all slice multiplexing techniques to improve the quality of the data obtained.

Although modifications and changes may be suggested by those skilled in the art, it is the intention of the Applicant to embody within the patent warranted hereon all changes and modifications as reasonably and properly come within the scope of the Applicant's contribution to the art.

1. A method for operating a magnetic resonance (MR) apparatus, comprising an MR data acquisition scanner comprising a radio frequency (RF) radiator, said method comprising:
with a computer, operating said MR data acquisition scanner to acquire MR signals from a subject, while the subject is situated in the MR scanner, by executing a slice multiplexing MR data acquisition sequence in which said MR signals are acquired simultaneously from at least two different slices of the subject;
in said computer identifying respective positions of said slices from which said MR signals are acquired simultaneously;
for each of said slices from which said MR signals are detected simultaneously, determining, in said computer, monoslice RF pulse parameters based on the respective position of that slice;
in said computer, correcting the monoslice RF pulse parameters for each slice based on at least one subject-specific parameter map provided to said computer, said at least one subject-specific parameter map comprising a spatial distribution of a scanner-specific parameter in said subject, and based on the respective position of that slice; and
in said computer, creating a multiband RF pulse that manipulates nuclear spins in said slices from which said MR signals are to be acquired simultaneously, based on said corrected monoslice RF pulse parameters, and operating said RF radiator in order to radiate said multiband RF pulse during said acquisition of said MR signals simultaneously from said at least two different slices.

2. A method as claimed in claim 1 comprising identifying the respective positions of said slices from which said MR signals are to be detected simultaneously by selecting one of said slices as an output slice, and then determining a distance of each further slice, among said slices from which said MR signals are to be detected simultaneously, from said output slice.

3. A method as claimed in claim 1 comprising determining said monoslice RF pulse parameter as a central excitation frequency for each of said slices from which said MR signals are to be detected simultaneously.

4. A method as claimed in claim 3 comprising determining a monoslice RF pulse phase progression of said monoslice RF pulse, and adjusting said monoslice RF pulse phase progression, with respect to each slice from which said MR signals are to be detected simultaneously, dependent on the corrected central excitation frequency of that slice.

5. A method as claimed in claim 1 comprising determining said monoslice RF pulse parameter as an amplitude scaling factor for each slice among said slices from which said MR signals are to be detected simultaneously.

6. A method as claimed in claim 1 wherein said MR data acquisition scanner comprises a basic field magnet that generates a basic magnetic field during acquisition of said MR signals, and determining said monoslice RF pulse parameter as a shimming parameter for said basic magnetic field for each slice from which said MR signals are to be detected simultaneously.

7. A method as claimed in claim 6 wherein said RF radiator comprises multiple transmission/reception channels, and comprising determining said shimming parameter as a shimming parameter that establishes settings of said at least two channels.

8. A method as claimed in claim 1 wherein operation of said RF radiator produces an RF field, and wherein said MR data acquisition scanner comprises a basic field magnet that generates a basic magnetic field during acquisition of said MR signals, and comprising using, as said at least one subject-specific parameter map, a map selected from the group consisting of a map showing a distribution of said RF field in said subject, and a map showing a distribution of said basic magnetic field in said subject.

9. A method as claimed in claim 1 comprising generating said multiband RF pulse as a totality of respective monoslice RF pulses that match the corrected monoslice RF pulse parameters.

10. A method as claimed in claim 1 wherein said MR data acquisition scanner comprises a gradient coil arrangement that generates gradient fields having a gradient moment, and comprising generating said multiband RF pulse using a gradient moment-based Maxwell term correction method.

11. A method as claimed in claim 1 wherein said MR data acquisition scanner comprises a basic field magnet that generates a basic magnetic field, and generating said multiband RF pulse using a shimming method for said basic magnetic field.

12. A magnetic resonance (MR) apparatus comprising:
an MR data acquisition scanner comprising a radio frequency (RF) radiator;
a computer configured to operate said MR data acquisition scanner to acquire MR signals from a subject, while the subject is situated in the MR scanner, by executing a slice multiplexing MR data acquisition sequence in which said MR signals are acquired simultaneously from at least two different slices of the subject;
said computer being configured to identify respective positions of said slices from which said MR signals are acquired simultaneously;
said computer being configured to determine, for each of said slices from which said MR signals are detected simultaneously, monoslice RF pulse parameters based on the respective position of that slice;
said computer being configured to correct the monoslice RF pulse parameters for each slice based on at least one subject-specific parameter map provided to said computer, said at least one subject-specific parameter map comprising a spatial distribution of a scanner-specific parameter in said subject, and based on the respective position of that slice; and
said computer being configured to create a multiband RF pulse that manipulates nuclear spins in said slices from which said MR signals are to be acquired simultaneously, based on said corrected monoslice RF pulse parameters, and to operate said RF radiator in order to radiate said multiband RF pulse during said acquisition of said MR signals simultaneously from said at least two different slices.

13. A non-transitory, computer-readable data storage medium encoded with programming instructions, said storage medium being loaded into a computer system of a magnetic resonance (MR) apparatus that comprises an MR data acquisition scanner comprising a radio frequency (RF) radiator, said programming instructions causing said computer system to:
operate said MR data acquisition scanner to acquire MR signals from a subject, while the subject is situated in the MR scanner, by executing a slice multiplexing MR data acquisition sequence in which said MR signals are acquired simultaneously from at least two different slices of the subject;
identify respective positions of said slices from which said MR signals are acquired simultaneously;
for each of said slices from which said MR signals are detected simultaneously, determine monoslice RF pulse parameters based on the respective position of that slice;
correct the monoslice RF pulse parameters for each slice based on at least one subject-specific parameter map provided to said computer, said at least one subject-specific parameter map comprising a spatial distribution of a scanner-specific parameter in said subject, and based on the respective position of that slice; and
create a multiband RF pulse that manipulates nuclear spins in said slices from which said MR signals are to be acquired simultaneously, based on said corrected monoslice RF pulse parameters, and operate said RF radiator in order to radiate said multiband RF pulse during said acquisition of said MR signals simultaneously from said at least two different slices.
